(19) United States
(12) Patent Application Publication
(10) Pub. No.: US 2015/0380306 A1
(43) Pub. Date: Dec. 31, 2015

(54) Method for Forming a Vertical Electrical Conductive Connection

(71) Applicant: Infineon Technologies AG, Neubiberg (DE)

(72) Inventor: Markus Menath, Regensburg (DE)

(21) Appl. No.: 14/320,402

(22) Filed: Jun. 30, 2014

(51) Int. Cl. H01L 21/768; H01L 23/522; H01L 23/532; H01L 23/528; H01L 21/311; H01L 21/3213

(52) U.S. Cl. CPC H01L 21/76877; H01L 21/31133; H01L 21/32133; H01L 21/76843; H01L 23/53266; H01L 23/528; H01L 23/5226

(57) ABSTRACT

A method for forming a vertical electrical conductive connection includes forming an electrically insulating layer including at least one hole reaching vertically through the electrically insulating layer and depositing an electrically conductive layer. A surface of the electrically conductive layer includes a recess at the location of the at least one hole of the electrically insulating layer. Further, the method includes forming a smoothing layer on the electrically conductive layer and etching the smoothing layer and the electrically conductive layer until the electrically conductive layer is removed above at least a part of a surface of the electrically insulating layer and remains within the at least one hole.

### TECHNICAL FIELD

Embodiments relate to the manufacturing of electrical devices and particular embodiments to a method for forming a vertical electrical conductive connection, a method for forming a semiconductor device and a method for forming a tungsten connection of a semiconductor device.

### BACKGROUND

The manufacturing of the wiring on a chip is a challenging task. Many process steps are required to obtain reliable electrically conductive horizontal lines and vertical connections at small scale. In general, it is desired to increase the reliability of electrical devices.

### SUMMARY

Some embodiments relate to a method for forming a vertical electrical conductive connection. The method comprises forming an electrically insulating layer comprising at least one hole reaching vertically through the electrically insulating layer and depositing an electrically conductive layer. A surface of the electrically conductive layer comprises a recess above the at least one hole of the electrically insulating layer. Further, the method comprises forming a smoothing layer on the electrically conductive layer and etching the smoothing layer and the electrically conductive layer until the electrically conductive layer is removed above at least a part of a surface of the electrically insulating layer and remains within the at least one hole.

Some embodiments relate to a method for forming a semiconductor device. The method comprises forming an electrically insulating layer comprising at least one hole reaching vertically through the electrically insulating layer and depositing an electrically conductive layer. A surface of the electrically conductive layer comprises a recess at the location of the at least one hole of the electrically insulating layer. Further, the method comprises forming a smoothing layer on the electrically conductive layer and etching the smoothing layer and the electrically conductive layer until the electrically conductive layer is removed above at least a part of a surface of the electrically insulating layer and remains within the at least one hole.

Some embodiments relate to a method for forming a tungsten connection of a semiconductor device. The method comprises forming an electrically insulating layer comprising at least one hole reaching vertically through the electrically insulating layer to a semiconductor substrate or a metal layer of the semiconductor device and depositing a tungsten layer after forming the electrically insulating layer. Further, the method comprises forming a smoothing layer on the tungsten layer and etching the smoothing layer and the tungsten layer until the tungsten layer is removed above at least a part of a surface of the electrically insulating layer and remains within the at least one hole.

### BRIEF DESCRIPTION OF THE DRAWINGS

Some embodiments of apparatuses and/or methods will be described in the following by way of example only, and with reference to the accompanying figures, in which

FIG. 1 shows a flowchart of a method for forming a vertical electrical conductive connection;

FIGS. 2a-2d show a schematic illustration of the manufacturing of a vertical electrical conductive connection;

FIG. 3 shows a flowchart of a method for forming a semiconductor device; and

FIG. 4 shows a flowchart of a method for forming a tungsten connection of a semiconductor device.

### DETAILED DESCRIPTION OF ILLUSTRATIVE EMBODIMENTS

Various example embodiments will now be described more fully with reference to the accompanying drawings in which some example embodiments are illustrated. In the figures, the thicknesses of lines, layers and/or regions may be exaggerated for clarity.

Accordingly, while further embodiments are capable of various modifications and alternative forms, some example embodiments thereof are shown by way of example in the figures and will herein be described in detail. It should be understood, however, that there is no intent to limit example embodiments to the particular forms disclosed, but on the contrary, example embodiments are to cover all modifications, equivalents, and alternatives falling within the scope of the disclosure. Like numbers refer to like or similar elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of further example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, acts, operations, elements and/or components, but do not preclude the presence or addition of one or more other features, integers, acts, operations, elements, components and/or groups thereof.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

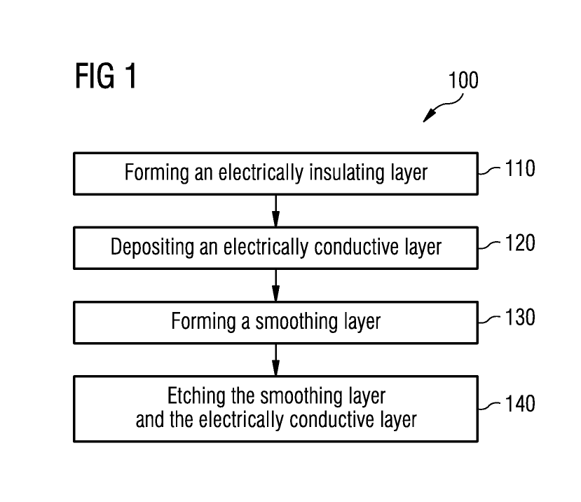

FIG. 1 shows a flowchart of a method for forming a vertical electrical conductive connection according to an embodiment. The method 100 comprises forming 110 an electrically insulating layer comprising at least one hole reaching vertically through the electrically insulating layer and depositing 120 an electrically conductive layer. A surface of the electrically conductive layer comprises a recess above the at least one hole of the electrically insulating layer. Further, the method comprises forming 130 a smoothing layer on the electrically conductive layer and etching 140 the smoothing layer and the electrically conductive layer until the electrically conductive layer is removed above at least a part of a surface of the electrically insulating layer and remains within the at least one hole.

An undesired influence of the recess of the electrically conductive layer during etching the electrically conductive layer may be reduced or avoided by implementing a smoothing layer before etching. A reproduction of the recess at a surface of the part of the electrically conductive layer remaining in the whole may be softened or avoided. In this way, an open contact may be avoided and/or the reliability of the vertical electrical conductive connection may be improved. Therefore, the reliability of an electrical device with a vertical electrical conductive connection formed according to the proposed concept may be improved.

A vertical electrical connection may be a connection between two horizontal metal lines or layers, between a substrate (e.g., semiconductor substrate) and a horizontal metal line or layer or between a pad metallization and a horizontal metal line or layer, for example. A horizontal electrically conductive structure (e.g., metal line or layer) may extend substantially in parallel to a surface of a substrate, the horizontal electrically conductive structure is manufactured on, while a vertical electrical conductive connection (e.g., contact or via) may extend substantially orthogonal to a surface of a substrate, the vertical electrical conductive connection is manufactured on.

The electrically insulating layer may be an inter metal dielectric IMD (e.g., borophosphosilicate glass BPSG or silicon dioxide) arranged between two horizontal metal lines or layers, between a substrate (e.g., semiconductor substrate) and a horizontal metal line or layer or between a pad metallization and a horizontal metal line or layer, for example. The electrically insulating layer may be formed by deposition (e.g., chemical vapor deposition, CVD) or a spin-on process, for example.

The electrically insulating layer comprises one or more holes reaching substantially vertically through the electrically insulating layer for enabling implementation of one or more vertical electrical conductive connections between two horizontal metal lines or layers, between a substrate (e.g., semiconductor substrate) and a horizontal metal line or layer or between a pad metallization and a horizontal metal line or layer, for example. The at least one hole may be formed by a masked (e.g., masked by structured photo resist layer) etching of the electrically insulating layer, for example. The at least one hole may comprise a lateral dimension (e.g., maximal, average or minimal lateral dimension) between 50 nm and 5 μm (or between 70 nm and 2 μm or between 100 nm and 1 μm).

The electrically conductive layer may be a metal layer or polysilicon layer, for example. For example, the electrically conductive layer may comprise or consist of tungsten, copper, aluminum or polysilicon or an alloy comprising tungsten, copper and/or aluminum. The electrically conductive layer may be deposited directly or indirectly (e.g., with a barrier layer structure in between) on the surface (e.g., the whole surface or a part of the surface) of the electrically insulating layer. In other words, the electrically conductive layer may be deposited directly after the electrically insulating layer or one or more other layers may be deposited after the electrically insulating layer and before the electrically conductive layer.

The at least one hole through the electrically insulating layer (or all holes) may be filled (e.g., substantially completely filled, neglecting voids remaining due to manufacturing limitations or constraints) with material of the electrically conductive layer during deposition of the electrically conductive layer. Since the filling of the hole consumes a part of the material of the electrically conductive layer, a recess is obtained at the surface of the electrically conductive layer above the hole, for example. The electrically conductive layer may be deposited by chemical vapor deposition, for example.

The smoothing layer may be a layer reproducing the topography of an adjacent or underlying surface with significantly reduced topography (e.g., non-conformal reproduction) or with substantially no topography. In other words, a surface of the smoothing layer may comprise a significantly lower topography than an adjacent or underlying surface, the smoothing layer is deposited on. For example, the recess at the location of the at least one hole of the surface of the electrically insulating layer comprises a first depth and a surface of the smoothing layer comprises a recess with a second depth or is recessless (comprises an substantially even surface) at the location of the at least one hole of the electrically insulating layer. In this case, the first depth (e.g., larger than 200 nm, larger than 300 nm or larger than 500 nm) is larger than the second depth (e.g., less than 100 nm, less than 80 nm or less than 50 nm). The depth of a recess may be measured from an ideal surface plane (e.g. desired flat surface or surface obtained by averaging over topography) vertically to a bottom or lowest point of the recess.

The smoothing layer may be formed by deposition (e.g., chemical vapor deposition, CVD) or a spin-on process, for example. The smoothing layer may be an organic layer. For example, the smoothing layer may be a bottom anti-reflection coating layer (e.g., planarizing BARC), a photo resist layer, a lacquer layer or an imide layer, for example. A bottom anti-reflection coating layer may be a layer of crosslinkable polymers that can be spin cast on wafers and may control the back reflection of light from the wafer surface, for example.

The electrically conductive layer may be removed from above the whole surface or only a part (e.g., keeping one or more horizontal electrically conductive lines) of the electrically insulating layer and remains within the at least one hole. In other words, the electrically conductive layer may be removed from the surface of the electrically insulating layer or a surface of one or more layers arranged on the surface of the electrically insulating layer (between the electrically insulating layer and the electrically conductive layer).

The smoothing layer and the electrically conductive layer may be etched during a common etching process. Since the smoothing layer fills the recess of the electrically conductive layer, the surface of the electrically conductive layer may already be reached outside the recess, while a part of the smoothing layer still covers the recess. Therefore, the etching surface may be kept very smooth during the common etching process resulting in a very smooth surface of the part of the electrically conductive layer remaining in the at least one hole, for example.

For example, the smoothing layer and the electrically conductive layer are etched by the same etching agent. In other words, an etching agent may be selected, which is able to etch the material of the smoothing layer and the electrically conductive layer. For example, the etching agent may be a fluorine-based etching agent (e.g., Sulfur hexafluoride SF₆).

For example, the smoothing layer and the electrically conductive layer are etched with similar etching rates (e.g., by the same etching agent). For example, the smoothing layer may be etched with a first etch rate during the common etching process and the electrically conductive layer may be etched with a second etching rate during the common etching process. The first etching rate may differ from the second etching rate by less than 30% (or by less than 20% or by less than 10%) of the second etching rate. In this way, the substantially flat topography of the smoothing layer may be kept during the etching of the smoothing layer and the electrically conductive layer.

Optionally, additionally or alternatively to the aspects mentioned above, the method 100 may further comprise depositing a barrier layer structure on the electrically insulating layer. Afterwards, the electrically conductive layer may be deposited on the barrier layer structure. The barrier layer structure may be an etch stop for the etching of the smoothing layer and the electrically conductive layer and/or may prevent or reduce a diffusion of the material of the electrically conductive layer into the electrically insulating layer or a semiconductor substrate or a metal line or layer at a bottom of the at least one hole through the electrically insulating layer.

The barrier layer structure may comprise or consist of titanium or titanium nitride. For example, the barrier layer structure may comprise a titanium layer and a titanium nitride layer.

The method 100 may further comprise etching the barrier layer structure until the barrier layer structure is removed above at least a part of a surface of the electrically insulating layer. The barrier layer structure may be etched after etching the smoothing layer and the electrically conductive layer. The barrier layer structure may be etched with an etching agent different from the etching agent used for etching the smoothing layer and the electrically conductive layer.

Optionally, additionally or alternatively to the aspects mentioned above, the method 100 may further comprise depositing a metal layer (e.g., copper Cu or aluminum Al) electrically contacting the part of the electrically conductive layer (e.g., titanium Ti) remaining in the at least one hole. The metal layer may be structured afterwards to form metal lines, for example.

For example, the method 100 may be implemented without a chemical-mechanical-polishing process CMP between the deposition of the electrically conductive layer and the deposition of the metal layer. A chemical-mechanical-polishing process for flattening the electrically conductive layer remaining after etching or for removing the electrically conductive layer by CMP instead of etching may be unnecessary due to the implementation of the smoothing layer, for example.

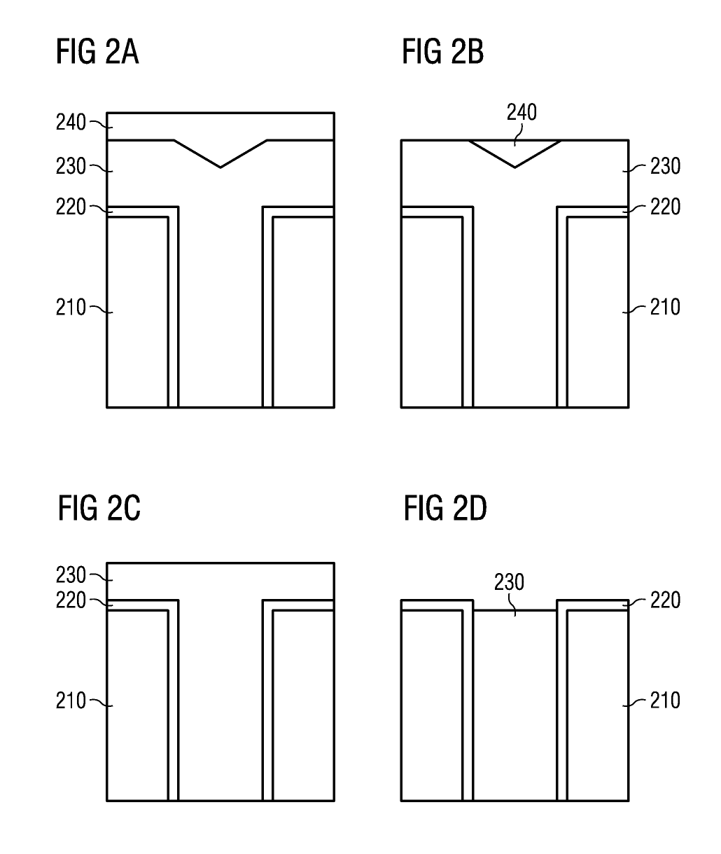

FIGS. 2a to 2d show an example of the manufacturing of a vertical electrical conductive connection. FIG. 2a shows a hole through an electrically insulating layer 210 (e.g., IMD/BPSG) and a barrier layer structure 220 (e.g., 5 nm Ti and 40 nm TiN) covering a horizontal surface of the electrically insulating layer 210 and the vertical walls of the electrically insulating layer 210. Further, an electrically conductive layer 230 (e.g., between 500 and 800 nm tungsten) is deposited on the barrier layer structure 220 and fills the remaining space in the hole. Since more material is required to fill the hole than at positions without a hole, a recess is obtained at the location of the hole. The electrically conductive layer 230 is covered by a smoothing layer 240 (e.g., 160 nm BARC). The smoothing layer comprises a higher thickness at the location of the hole than at positions without hole due to its smoothing properties. FIGS. 2a and 2c show the layer stack at different times during the etching of the smoothing layer 240 and the electrically conductive layer 230. First the smoothing layer 240 is removed at positions without a hole, while a part of the smoothing layer 240 still remains in the recess of the electrically conductive layer 230 as shown in FIG. 2b. The electrically conductive layer 230 is etched back at positions without hole and the remaining part of the smoothing layer 240 at the location of the smoothing layer 240 is etched as shown in FIG. 2c. FIG. 2d shows the hole after the etching of the smoothing layer 240 and the electrically conductive layer 230. The surface of the part of the electrically conductive layer 230 remaining in the hole is substantially flat and is located below the level of the horizontal surface build by the remaining barrier layer structure 220 due to a slight over etch to ensure a sufficiently complete removal of the electrically conductive layer 230 from desired parts of the horizontal surface, for example.

For example, FIGS. 2a to 2d may show an example of a planarization with BARC or a tungsten-etchback with BARC planarization. For example, the etch rate of the BARC is similar or equal to the etch rate of tungsten (e.g. ER(BARC)=ER(tungsten)).

More details and aspects are mentioned in connection with embodiments described above or below (e.g., regarding the electrically insulating layer, the electrically conductive layer and/or the smoothing layer).

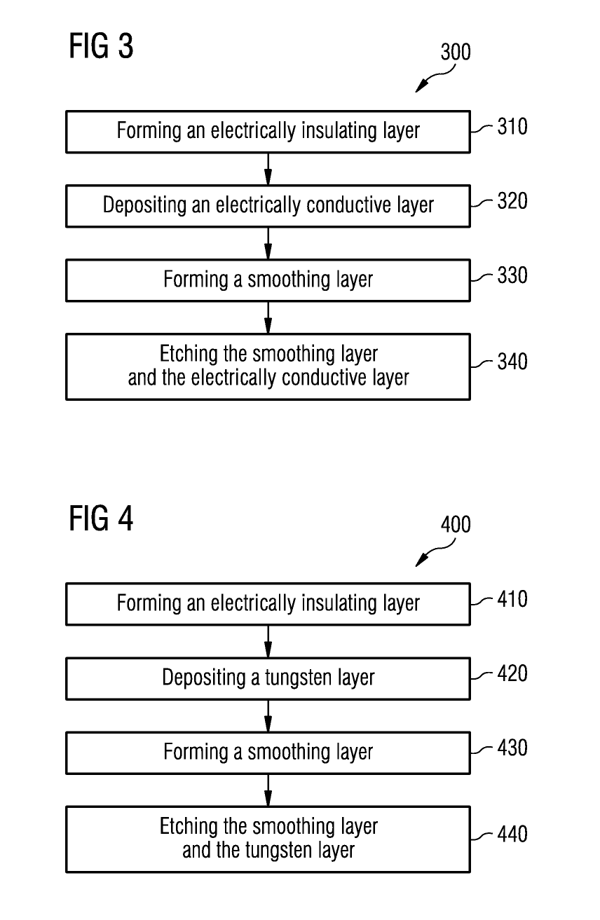

FIG. 3 shows a flowchart of a method for forming a semiconductor device according to an embodiment. The method 300 comprises forming 110 an electrically insulating layer comprising at least one hole reaching vertically through the electrically insulating layer and depositing 120 an electrically conductive layer. A surface of the electrically conductive layer comprises a recess at the location of the at least one hole of the electrically insulating layer. Further, the method comprises forming 130 a smoothing layer on the electrically conductive layer and etching 140 the smoothing layer and the electrically conductive layer until the electrically conductive layer is removed above at least a part of a surface of the electrically insulating layer and remains within the at least one hole.

An undesired influence of the recess of the electrically conductive layer during etching the electrically conductive layer may be reduced or avoided by implementing a smoothing layer before etching. In this way, an open contact may be avoided and/or the reliability of the vertical electrical conductive connection may be improved. Therefore, the reliability of a semiconductor device with a vertical electrical conductive connection formed according the proposed concept may be improved.

The semiconductor device may be an electrical device formed on a semiconductor substrate (semiconductor die). The semiconductor substrate may be a silicon-based semiconductor substrate, a silicon carbide-based semiconductor substrate, a gallium arsenide-based semiconductor substrate or a gallium nitride-based semiconductor substrate, for example.

More details and aspects are mentioned in connection with embodiments described above or below (e.g., regarding the electrically insulating layer, the electrically conductive layer and/or the smoothing layer). The method 300 may comprise one or more optional additional acts corresponding to one or more aspects mentioned in connection with the proposed concept or one or more embodiments described above or below (e.g., FIG. 1, 2 or 4).

FIG. 4 shows a flowchart of a method for forming a tungsten connection of a semiconductor device. The method 400 comprises forming 410 an electrically insulating layer comprising at least one hole reaching vertically through the electrically insulating layer to a semiconductor substrate or a metal layer of the semiconductor device and depositing 420 a tungsten layer after forming the electrically insulating layer. Further, the method 400 comprises forming 430 a smoothing layer on the tungsten layer and etching 440 the smoothing layer and the tungsten layer until the tungsten layer is removed above at least a part of a surface of the electrically insulating layer and remains within the at least one hole.

An undesired influence of the recess of the tungsten layer during etching the tungsten layer may be reduced or avoided by implementing a smoothing layer before etching. In this way, an open contact may be avoided and/or the reliability of the vertical electrical conductive connection may be improved. Therefore, the reliability of a semiconductor device with a vertical electrical conductive connection formed according the proposed concept may be improved.

More details and aspects are mentioned in connection with embodiments described above or below (e.g., regarding the electrically insulating layer, the electrically conductive layer and/or the smoothing layer). The method 400 may comprise one or more optional additional acts corresponding to one or more aspects mentioned in connection with the proposed concept or one or more embodiments described above or below (e.g., FIG. 1, 2 or 3).

For example, the smoothing layer may be a bottom anti-reflection coating layer.

Some embodiments relate to a tungsten etch back with BARC planarization. Based on the proposed concept a very strong etch back of the tungsten in the hole (contact hole or via) may be avoided during an all over tungsten etch back (WEB), which may be caused by a topology difference of the tungsten deposition above the contact hole or via and the over etch, which should guarantee residual freedom. Consequently, open vias due to back-moving tungsten may be avoided.

By depositing a planarizing BARC layer over the tungsten and a suitable etch process, the depth of the tungsten etch within the hole may be significantly reduced, which may result in a quality enhancement. Further, the etch back may be similar to the result obtained by CMP.

The BARC may fill the recesses, which emerge during the tungsten deposition. An etch process may be used, which comprises an etch rate for BARC corresponding to the tungsten etch rate.

The proposed concept may be implemented whenever a topology difference at a dry chemical etching should be compensated (e.g., poly etch back).

Example embodiments may further provide a computer program having a program code for performing one of the above methods, when the computer program is executed on a computer or processor. A person of skill in the art would readily recognize that acts of various above-described methods may be performed by programmed computers. Herein, some example embodiments are also intended to cover program storage devices, e.g., digital data storage media, which are machine or computer readable and encode machine-executable or computer-executable programs of instructions, wherein the instructions perform some or all of the acts of the above-described methods. The program storage devices may be, e.g., digital memories, magnetic storage media such as magnetic disks and magnetic tapes, hard drives, or optically readable digital data storage media. Further example embodiments are also intended to cover computers programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. It will thus be appreciated that those skilled in the art will be able to devise various arrangements that, although not explicitly described or shown herein, embody the principles of the disclosure and are included within its spirit and scope. Furthermore, all examples recited herein are principally intended expressly to be only for pedagogical purposes to aid the reader in understanding the principles of the disclosure and the concepts contributed by the inventor(s) to furthering the art, and are to be construed as being without limitation to such specifically recited examples and conditions. Moreover, all statements herein reciting principles, aspects, and embodiments of the disclosure, as well as specific examples thereof, are intended to encompass equivalents thereof.

Functional blocks denoted as “means for . . . ” (performing a certain function) shall be understood as functional blocks comprising circuitry that is configured to perform a certain function, respectively. Hence, a “means for s.th.” may as well be understood as a “means configured to or suited for s.th.”. A means configured to perform a certain function does, hence, not imply that such means necessarily is performing the function (at a given time instant).

Functions of various elements shown in the figures, including any functional blocks labeled as “means”, “means for providing a sensor signal”, “means for generating a transmit signal.”, etc., may be provided through the use of dedicated hardware, such as “a signal provider”, “a signal processing unit”, “a processor”, “a controller”, etc. as well as hardware capable of executing software in association with appropriate software. Moreover, any entity described herein as “means”, may correspond to or be implemented as “one or more modules”, “one or more devices”, “one or more units”, etc. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

It should be appreciated by those skilled in the art that any block diagrams herein represent conceptual views of illustrative circuitry embodying the principles of the disclosure. Similarly, it will be appreciated that any flowcharts, flow diagrams, state transition diagrams, pseudo code, and the like represent various processes which may be substantially represented in computer readable medium and so executed by a computer or processor, whether or not such computer or processor is explicitly shown.

Furthermore, the following claims are hereby incorporated into the detailed description, where each claim may stand on its own as a separate example embodiment. While each claim may stand on its own as a separate example embodiment, it is to be noted that—although a dependent claim may refer in the claims to a specific combination with one or more other claims—other example embodiments may also include a combination of the dependent claim with the subject matter of each other dependent or independent claim. Such combinations are proposed herein unless it is stated that a specific combination is not intended. Furthermore, it is intended to include also features of a claim to any other independent claim even if this claim is not directly made dependent to the independent claim.

It is further to be noted that methods disclosed in the specification or in the claims may be implemented by a device having means for performing each of the respective acts of these methods.

Further, it is to be understood that the disclosure of multiple acts or functions disclosed in the specification or claims may not be construed as to be within the specific order. Therefore, the disclosure of multiple acts or functions will not limit these to a particular order unless such acts or functions are not interchangeable for technical reasons. Furthermore, in some embodiments a single act may include or may be broken into multiple sub acts. Such sub acts may be included and part of the disclosure of this single act unless explicitly excluded.

What is claimed is:

1. A method for forming a vertical electrical conductive connection, the method comprising:
forming an electrically insulating layer that includes a hole that extends vertically through the electrically insulating layer;
depositing an electrically conductive layer, wherein a surface of the electrically conductive layer comprises a recess above the hole of the electrically insulating layer;
forming a smoothing layer on the electrically conductive layer; and
etching the smoothing layer and the electrically conductive layer until the electrically conductive layer is removed above at least a part of a surface of the electrically insulating layer and remains within the hole.

2. The method of claim 1, wherein the recess above the hole of the electrically insulating layer comprises a first depth, wherein the smoothing layer comprises a recess with a second depth or is recessless at the location of the hole of the electrically insulating layer, wherein the first depth is larger than the second depth.

3. The method of claim 2, wherein the first depth is larger than 200 nm.

4. The method of claim 2, wherein the second depth is less than 100 nm.

5. The method of claim 1, wherein etching the smoothing layer and the electrically conductive layer comprises etching the smoothing layer and the electrically conductive during a common etching process.

6. The method of claim 5, wherein the smoothing layer and the electrically conductive layer are etched by the same etching agent.

7. The method of claim 6, wherein the etching agent is a fluorine-based etching agent.

8. The method of claim 5, wherein the smoothing layer is etched with a first etch rate during the common etching process and the electrically conductive layer is etched with a second etching rate during the common etching process, wherein the first etching rate differs from the second etching rate by less than 30% of the second etching rate.

9. The method of claim 1, wherein the smoothing layer is one of a group comprising a bottom anti-reflection coating layer, a photo resist layer, a lacquer layer and an imide layer.

10. The method of claim 1, wherein the electrically conductive layer comprises electrical conductive material selected from the group consisting of tungsten, copper and aluminum.

11. The method of claim 1, wherein the hole through the electrically insulating layer reaches to a semiconductor substrate or a metal layer below the electrically insulating layer.

12. The method of claim 1, further comprising depositing a barrier layer structure on the electrically insulating layer, wherein the electrically conductive layer is deposited on the barrier layer structure.

13. The method of claim 12, wherein the barrier layer structure comprises a material selected from the group consisting of titanium and titanium nitride.

14. The method of claim 12, further comprising etching the barrier layer structure until the barrier layer structure is removed above at least a part of a surface of the electrically insulating layer.

15. The method of claim 1, further comprising depositing a metal layer electrically contacting the part of the electrically conductive layer remaining in the hole.

16. The method of claim 15, wherein the method is implemented without a chemical-mechanical-polishing process between the deposition of the electrically conductive layer and the metal layer.

17. The method of claim 1, wherein the hole comprises a lateral dimension between 50 nm and 5 μm.

18. A method for forming a semiconductor device, the method comprising:
forming an electrically insulating layer that includes a hole that extends vertically through the electrically insulating layer;
depositing an electrically conductive layer, wherein a surface of the electrically conductive layer comprises a recess at the location of the hole of the electrically insulating layer;
forming a smoothing layer over the electrically conductive layer; and
etching the smoothing layer and the electrically conductive layer until the electrically conductive layer is removed above at least a part of a surface of the electrically insulating layer and remains within the hole.

19. A method for forming a tungsten connection of a semiconductor device, the method comprising:
forming an electrically insulating layer that includes a hole reaching that extends vertically through the electrically insulating layer to a semiconductor substrate or a metal layer of the semiconductor device;
depositing a tungsten layer after forming the electrically insulating layer;
forming a smoothing layer on the tungsten layer; and
etching the smoothing layer and the tungsten layer until the tungsten layer is removed above at least a part of a surface of the electrically insulating layer and remains within the hole.

20. The method of claim 19, wherein the smoothing layer is a bottom anti-reflection coating layer.
